(19) United States
(12) Patent Application Publication
(10) Pub. No.: US 2008/0024195 A1
(43) Pub. Date: Jan. 31, 2008

(54) Digital Temperature Compensation for Battery Charging Circuits

(75) Inventor: John S.K. So, Fremont, CA (US)

Correspondence Address: ADVANCED ANALOGIC TECHNOLOGIES, 830 EAST ARQUES AVE, SUNNYVALE, CA, 94085, US

(73) Assignee: ADVANCED ANALOGIC TECHNOLOGIES, INC., Sunnyvale, CA (US)

(21) Appl. No.: 11/835,840

(22) Filed: Aug. 8, 2007

Related U.S. Application Data
(63) Continuation of application No. 11/023,017, filed on Dec. 23, 2004.

(51) Int. Cl. H02J 7/00; H01L 35/00

(52) U.S. Cl. 327/512

(57) ABSTRACT

A temperature control circuit for a battery charger includes a counter and a digital to analog converter for adjusting a current output of the charger based on a value stored in the counter. A first comparator increments or decrements the counter based on the difference between the temperature of the charger and a desired temperature. A reset circuit zeros the counter when the temperature of the charger has exceeded an upper threshold and subsequently maintains the counter at zero until the temperature of the charger has fallen below a lower threshold.

### RELATED APPLICATIONS

This application is a continuation in part of U.S. patent application Ser. No. 11/023,017 filed Dec. 23, 2004.

### BACKGROUND OF THE INVENTION

In the past, a range of different battery types have been developed to power portable electronic devices. Specific types or chemistries include Nickel Cadmium (Ni-Cad), Nickel Metal Hydride (Ni-MH) and Lithium-Ion (Li-Ion). Of these, Li-Ion batteries are increasingly popular due to their high output voltage and power density. This makes Li-Ion batteries ideal for a wide range of application including cellular telephones, personal music players and laptop computers.

Numerous charging circuits have been developed to support the rechargeable batteries used in portable electronic devices. The basic function of these circuits is to provide power at the correct current and voltage to match battery requirements. Often this is done in multiple stages.

For example, for Li-Ion rechargeable batteries, a battery condition mode or tickle charge stage is introduced first, followed by a rapid charge stage when constant current at a high rate is applied until the battery voltage reaches a predefined threshold. Next, a constant voltage stage is applied until the charger current drops below a lower threshold at which point the charging cycle terminates. Ni-Cad and Ni-MH batteries, on the other hand, use an initial activation stage in which a low level current is supplied to the battery. The activation stage is followed by a rapid charge stage where the battery is charged at a relatively high rate. A trickle stage may then be used to top off the voltage of charged batteries.

In practice, charging circuits generally monitor a number of parameters such as battery voltage and the current flowing to the battery. Other parameters may have to be monitored as well. For example, U.S. Pat. Nos. 6,507,172 and 6,148,652 (both incorporated in this document by reference) both disclose chargers that allow portable devices to be recharged using power drawn from a USB (universal serial bus) connection. For chargers of this type, it is generally necessary to monitor the load applied by the charger to the USB bus. This prevents overloading of the USB bus which can result in data lose or other failures.

To save cost, battery charging circuits are typically implemented as stand alone integrated circuits. For the typical case, where the charger controls its output using a linear regulator, this means that the integrated circuit includes a power control transistor. The power control transistor generates heat which increases the temperature of the integrated circuit in which it is included. For this reason, it becomes necessary to monitor temperature and reduce output to prevent thermal overloading. For example, U.S. Pat. No. 6,507,172 (incorporated previously) discloses a temperature feedback that uses a linear regulator to reduce output current and maintain operating temperature within a predetermined range.

### SUMMARY OF THE INVENTION

A temperature control circuit for a battery charger includes a digital to analog converter connected to receive the value stored in an up/down counter. The digital to analog converter generates a control output signal based on the counter value. The control output signal is used to regulate the output current of the battery charger.

A first comparator increments or decrements the counter based on the difference between the temperature of the charger and a desired temperature. The value in the counter is increased during each clock cycle when the temperature of the circuit is below the desired temperature. The value in the counter is decreased during each clock cycle when the temperature of the circuit is above the desired temperature.

A reset circuit zeros the counter when the temperature of the charger has exceeded an upper threshold and subsequently maintains the counter at zero until the temperature of the charger has fallen below a lower threshold. The reset circuit includes a second comparator and a multiplexer. One input of the second comparator monitors the temperature of the charger. The second is selects between two voltages representing the high and the low thresholds. When the battery charger temp exceeds the high threshold, the second comparator resets the counter and switches the multiplexer. As a result, the second comparator continues to monitor and reset the counter until the temperature of the charger has fallen below the low threshold.

### BRIEF DESCRIPTION OF THE DRAWINGS

FIG. 1 is a block diagram of a temperature control loop as provided by an embodiment of the present invention.

FIG. 2 is a graph showing the relationship between temperature and voltage produced by the temperature sensor of FIG. 1.

FIG. 3 is a graph showing the signal control output produced by the temperature control loop as a function of time.

FIG. 4 is a graph showing temperature as function of time for a representative period of operation for the temperature control loop of FIG. 1.

### DETAILED DESCRIPTION OF THE PREFERRED EMBODIMENTS

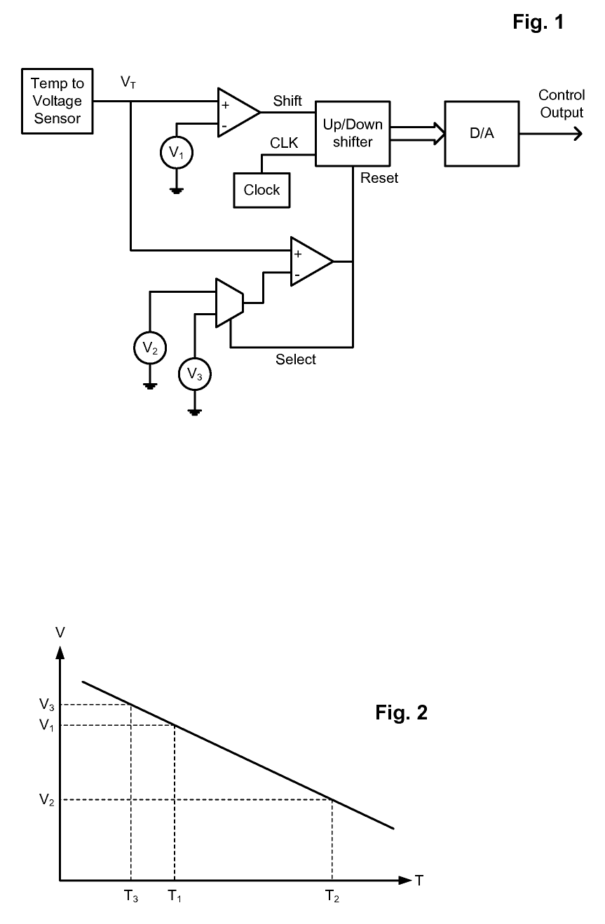

The present invention includes a temperature control loop (and associated method) for battery charging and other circuits. As show in FIG. 1, a representative implementation of the temperature loop includes a temperature to voltage sensor that produces an output V_{T}. As shown in FIG. 2, V_{T} is inversely related to temperature T (increasing T decreases V_{T}). Of course, it should be appreciated that other embodiments may be constructed where V_{T} is some other function of T such as where increasing T increases V_{T}.

The output V_{T} forms the input of a first comparator. The second input to the first comparator is a voltage V₁. V₁ corresponds to the desired temperature (or target temperature) for the semiconductor that includes the temperature control loop. This means that V_{T} is equal to V₁ when the semiconductor is operating at the target temperature.

The output of the first comparator controls up and down operation of a shifter. The shifter also receives a clock input from a clock generator. The result is that, on a clock by clock basis, the count in the shifter increases when V_{T} is less that V₁ and decreases when V_{T} is greater than V₁. The n-bit output of the shifter is converted by a digital to a control output signal. In turn, this means that the control output signal decreases during each clock cycle where V_{T} is greater V₁ and increases when V_{T} is less than V₁.

As shown in FIG. 1, the control loop also includes a second comparator. Like the first comparator, the second comparator receives the voltage V_{T}. This voltage is compared to one of two different voltages: V₂ and V₃. V₂ and V₃ correspond to the temperatures T₂ and T₃, respectively where T₂ and T₃ are the upper and lower temperature limits for the temperature control loop. V₂ and V₃ are selected by a multiplexer. The multiplexer is controlled, in turn by the output of the second comparator. This same output of the second comparator also functions as a reset signal to the shifter. The overall effect is that the second comparator creates two states: in the first state the shifter is not reset and the V₂ input is selected by the multiplexer, in the second state the shifter is reset and the V₃ input is selected by the multiplexer.

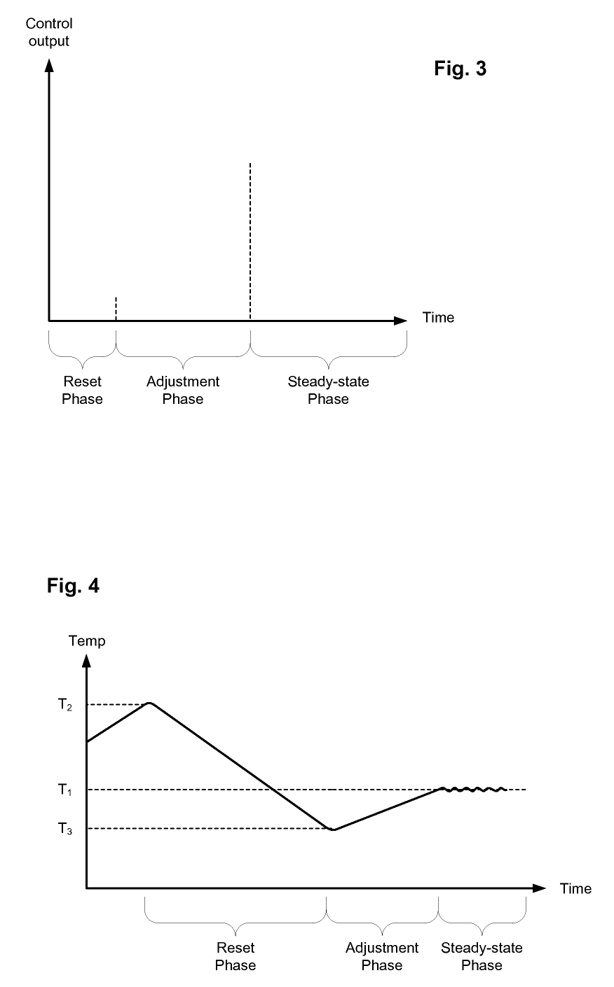

During operation, temperatures in excess of T₂ cause the second comparator to reset the shifter. This causes the control output signal to drop to its minimum level. At the same time, the output of the multiplexer is switched from V₂ to V₃. This is shown as the reset phase in FIGS. 3 and 4. During the reset phase, the low level of the control output signal causes the temperature T to fall. It continues to fall until it is reaches T₃. At that point, the output of the second comparator enables the shifter and switches the multiplexer from V₃ to V₂. The enabled shifter then counts up under control of the output of the first comparator. This causes the output control signal to increase (See the adjustment phase of FIG. 3) as well as increasing temperature T (adjustment phase of FIG. 4). Temperature T continues to increase until it matches T₁. At that point, the output of the first comparator increases or decreases the contents of the shifter to maintain temperature T around T₁.

What is claimed is:

1. A temperature control circuit for an integrated circuit that includes a battery charger, the circuit comprising:
a counter;
a digital to analog converter for adjusting a current output of the integrated circuit based on a value stored in the counter; and
a first comparator that causes the value in the counter to increment or decrement based on the difference between the temperature of the integrated circuit and a desired temperature.

2. A temperature control circuit as recited in claim 1 that further comprises: a reset circuit that causes the counter to be set to zero when the temperature of the integrated circuit has exceeded an upper threshold and maintained at zero until the temperature of the integrated circuit has fallen below a lower threshold.

3. A temperature control circuit as recited in claim 1 in which the counter is incremented or decremented synchronously with a clock signal.

4. A temperature control circuit for an integrated circuit that produces an output current for charging a battery, the circuit comprising:
a sensor configured to generate a voltage Vₜ in proportion to the temperature of the integrated circuit;
a counter for storing a value;
a first circuit that causes the value in the counter to be incremented if Vₜ exceeds a first reference voltage V₁ and to be decremented if Vₜ is less that V₁;
a second circuit that causes the counter to be set to zero when Vₜ exceeds a second reference voltage V₂ and maintained at zero until Vₜ has fallen below a third reference voltage V₃; and
a third circuit for adjusting the output current in proportion to the value stored in the counter.

5. A temperature control circuit as recited in claim 4 where the temperature sensor is configured so that Vₜ is inversely proportional to the temperature of the integrated circuit.

6. A temperature control circuit as recited in claim 4 where the first circuit includes a first comparator connected to compare Vₜ and V₁ and where the output of the first comparator is connected to cause the counter to select between counting up or counting down.

7. A temperature control circuit as recited in claim 4 where the second circuit includes:
a multiplexer configured to select V₃ when Vₜ exceeds V₂ and to select V₂ when Vₜ has fallen below V₃; and
a second comparator configured to compare the output of the multiplexer to a voltage representing the temperature of the integrated circuit.

8. A temperature control circuit as recited in claim 4 in which the counter is incremented or decremented synchronously with a clock signal.

9. A temperature control circuit as recited in claim 4 in which the third circuit includes a digital to analog converter for converting the value stored in the counter to a signal that controls the output current.

10. A temperature control circuit for an integrated circuit that produces an output current for charging a battery, the circuit comprising:
a counter;
a digital to analog converter for adjusting a current output of the integrated circuit based on a value stored in the counter;
a first comparator that causes the value in the counter to increment during each cycle of a clock where the temperature of the integrated circuit is below a desired temperature, the first comparator causing the value in the counter to decrement during each cycle of the clock where the temperature of the integrated circuit is above a desired temperature; and
a reset circuit that causes the counter to be set to zero when the temperature of the integrated circuit has exceeded an upper threshold and maintained at zero until the temperature of the integrated circuit has fallen below a lower threshold.

11. A temperature control circuit as recited in claim 10 in which the reset circuit further comprises:
a multiplexer configured to select between a voltage corresponding to the upper threshold and a voltage corresponding to a lower threshold; and
a second comparator configured to compare the output of the multiplexer to a voltage representing the temperature of the integrated circuit.
